(19) United States
(12) Patent Application Publication
(10) Pub. No.: US 2007/0020946 A1
(43) Pub. Date: Jan. 25, 2007

(54) Method for modifying surface of substrate and method for manufacturing semiconductor device

(76) Inventor: Yasuo Tanaka, Tokyo (JP)

Correspondence Address: RABIN & Berdo, PC, 1101 14TH STREET, NW, SUITE 500, WASHINGTON, DC, 20005, US

(21) Appl. No.: 11/475,242

(22) Filed: Jun. 27, 2006

(30) Foreign Application Priority Data
Jun. 27, 2005 (JP) 2005-186609
May 15, 2006 (JP) 2006-135274

(51) Int. Cl. H01L 21/31

(52) U.S. Cl. 438/758

(57) ABSTRACT

An insulating film is formed on a substrate selected from a group containing a BT resin substrate and an epoxy resin substrate. Copper wirings and copper posts including wirings are formed on the insulating film. Plasma processing is effected on exposed surfaces of the insulating film, copper wirings and copper posts provided over the semiconductor substrate, using nitrogen-type gas. An encapsulating portion is formed which covers and seals the exposed surfaces.

### BACKGROUND OF THE INVENTION

1. Field of the Invention

The present invention relates to a method for modifying the surface of a substrate and a method for manufacturing a semiconductor device. The present invention relates particularly to a method for modifying the surface of a substrate (including a so-called semiconductor chip), which is used for enhancing adhesion between the substrate, an insulating film provided on the substrate and/or each of constituent elements using copper (Cu) as a material like copper wirings and copper posts, which are provided on the insulating film, and an encapsulating resin, and ensuring moisture-resistance reliability, and a method for manufacturing a semiconductor device. This is counterparts of and claim priority to Japanese patent application Serial Number 2005-186609 filed on Jun. 27, 2005, and Japanese patent application Serial Number 2006-135274 filed on May 15, 2006, the subject matter of which is incorporated herein by reference.

2. DESCRIPTION OF THE RELATED ART

With developments in finer semiconductor process rules, there are tendencies to make wirings formed on a substrate finer and more narrow the interval between the adjacent wirings. With such developments, it is becoming difficult to ensure mutual satisfactory adhesion among an insulating film formed on the substrate, constituent elements like copper wirings formed on the insulating film and an encapsulating resin for sealing these constituent elements, and moisture-resistance reliability.

Under the present circumstances, the surface of each copper wiring provided on the substrate is oxidized (copper wirings lying inside a printed circuit board are subjected to darkening processing and the surface of each copper wiring is surface-roughened) to thereby ensure adhesion of an encapsulating resin.

There has been a demand for further downsizing and thinning of a packaged semiconductor device. In order to meet this demand, there has been proposed a package form called a wafer level chip size package (hereinafter also called simply “W-CSP”), whose package outer size is substantially identical to an outer size of a semiconductor chip.

A configuration of the conventional W-CSP will now be explained with reference to FIGS. 2 and 3.

FIG. 2(A) is a schematic plan view as viewed from an upper surface of a semiconductor device, for describing the configuration of the semiconductor device, and FIG. 2(B) is a schematic fragmentary plan view showing, in an enlarged form, a partial area surrounded by a solid line 11 of FIG. 2(A) in order to describe the relationship of connections between copper wiring patterns and copper posts. FIG. 3 is a schematic view showing a cut cross-section cut along broken line I-I of FIG. 2(A).

The W-CSP includes a semiconductor chip 30. The semiconductor chip 30 is provided with a plurality of electrode pads 34 along its peripheral edge. These electrode pads 34 are disposed along the peripheral edge of the semiconductor chip 30. An insulating film 40 is formed so as to expose these plural electrode pads 34. A plurality of copper wirings 42 connected to their corresponding exposed electrode pads 34 are formed on the surface of the insulating film 40.

Copper posts 46 are provided on the copper wirings 42 each corresponding to a so-called redistribution wiring layer. And an encapsulating portion 44 is provided which covers the insulating film 40 and the copper wirings 42 and exposes the top faces of the copper posts 46. Further, external terminals 47 are provided on the top faces of the copper posts 46.

There has been known, for example, a method for manufacturing a semiconductor device, wherein in a manufacturing process of the W-CSP having such a configuration, ashing processing is performed by argon gas, oxygen gas or the like prior to the formation of an encapsulating portion for the purpose of enhancing adhesion of the insulating film, copper wirings and/or copper posts to the encapsulating portion (refer to, for example, a patent document 1 (Japanese Unexamined Patent Publication No. 2004-014789)).

There has also been known a semiconductor device capable of, while eliminating the need for an underfill resin between a semiconductor chip and a multilayered wiring board (printed circuit board), relaxing deformation stress acting on metal bumps by flexible conductive members and an insulating resin layer having elasticity to thereby enhance packaging reliability, avoiding damaging of peripheral devices including the printed circuit board, etc. at regenerative processing, and realizing low cost, and its manufacturing method (refer to, for example, a patent document 2 (Japanese Unexamined Patent Publication No. 2001-135663)).

There has further been known a method for manufacturing a semiconductor device, wherein the surfaces of electrode portions of pad portions in a semiconductor chip formed on a substrate are plasma-cleaned, then ultrasound is applied to the electrode portions in a solder-molten solution to remove an oxide film placed on the surfaces of the electrode portions, and thereafter solder bumps are respectively formed directly on the surfaces of the electrode portions, thereby bonding the solder bumps onto the surfaces of the electrode portions easily and robustly (refer to, for example, a patent document 3 (Japanese Unexamined Patent Publication No. 2000-133669)).

There is however a fear that if an attempt is made to realize further increases in frequency and speed of a device in particular after the execution of such darkening processing as described above, then the operating speed and reliability of the device are impaired due to so-called skin effects caused by surface-roughening of each wiring.

It is extremely difficult to ensure satisfactory adhesion between the constitutions with copper as the material, such as the insulating film, copper wirings, etc. and the encapsulating resin (encapsulating portion) associated with these, and moisture-resistance reliability thereof in conjunction with each other by virtue of the processing processes disclosed in the patent documents 1, 2 and 3. That is, the conventional processing involves the following problems.

(1) When ashing processing (plasma processing) is performed, it is necessary to perform ashing condition statements every various insulating materials. It is however difficult to find a condition that satisfies moisture-resistance reliability in conjunction with adhesion. That is, it is difficult to optimize modifications of the surfaces of an insulating film material and coexistent copper wirings simultaneously.

(2) When finer process rules go forward and the interval between adjacent wirings becomes small, the moisture-resistance reliability is not met in particular.

(3) When the ashing condition changes, adhesive power of the resin to copper (each constituent element using copper as the material) varies and its optimization is difficult.

(4) Since there are temporal restrictions on the condition on the storage of a processed sample and processing waiting up to resin encapsulation after the ashing processing, TAT (Turn Around Time) in the manufacturing process of the semiconductor device cannot be shortened and its management is cumbersome.

(5) When there is a problem about handling up to the execution of an encapsulating step after the ashing processing, it is not possible to obtain satisfactory adhesion of the resin to the copper wirings and/or copper posts.

### SUMMARY OF THE INVENTION

The present invention has been made in view of the problems of the above-described related arts. That is, it is an object of the present invention to provide a method for processing a semiconductor substrate and a method for manufacturing a semiconductor device, both of which ensure satisfactory adhesion between an insulating film formed on a substrate and/or constituent elements using copper as a material, such as wirings, electrode posts and the like formed on the insulating film, and an encapsulating resin for sealing these constituent elements, and enhance moisture-resistance reliability.

Upon resolving the above-described problems, a method for modifying a substrate's surface, according to the present invention includes the following steps.

That is, a substrate which corresponds to a substrate having an insulating film and constituent elements with copper as a material, including wirings provided on the insulating film, and which is selected from a group containing a BT resin substrate and an epoxy resin substrate, is prepared.

Plasma processing is effected on the substrate using nitrogen-type gas.

A method for manufacturing a semiconductor device, according to the present invention includes such steps as shown below.

That is, an insulating film is formed on a semiconductor substrate.

Constituent elements with copper as a material, including wirings are formed on the insulating film.

Plasma processing is effected on exposed surfaces of the insulating film and the constituent elements provided on the semiconductor substrate, using nitrogen-type gas.

An encapsulating portion is formed which seals the exposed surfaces of the insulating film and the constituent elements so as to cover the exposed surfaces thereof.

According to the substrate's surface modifying method of the present invention and the semiconductor device manufacturing method thereof, plasma processing using nitrogen gas is effected on exposed surfaces of an insulating film and constituent elements with copper as a material to thereby make it possible to form surfaces that exhibit larger (chemical) bonding, without performing surface-roughening of the exposed surfaces, which impairs electrical characteristics. Accordingly, the exposed surfaces subjected to the plasma processing provides a further improvement in adhesion to an encapsulating resin and makes it possible to remarkably suppress aged degradation of adhesive power.

Further, moisture-resistance reliability is enhanced by virtue of an improvement in adhesion of the encapsulating resin to the respective surfaces of the insulating film and the constituent elements using copper as the material.

Furthermore, plasma processing, or plasma processing and heat treatment are performed to make it possible to set the ratio of Cu₂O to 50% even at a minimum with respect to the ratio of existence of copper per unit area of the surface of a structure with copper as the material. If done in this way, then the power of adhesion between the structure with copper as the material and the encapsulating portion can be noticeably increased. Further, even though the structure is placed under high-temperature and high-humidity environments if done in this way, the degree of aged degradation of the power of adhesion between the structure with copper as the material and the encapsulating portion can be more reduced.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a graph for describing the evaluation of adhesive power;

FIG. 2(A) is a plan view for describing the configuration of a conventional W-CSP;

FIG. 2(B) is a partly enlarged view showing, in an enlarged form, a partial area of FIG. 2(A); and

FIG. 3 is a schematic view showing a cut section of the conventional W-CSP;

FIG. 4 is a graph showing the ratio of by-status existence of copper; and

FIG. 5 is a graph (2) for explaining the evaluation of adhesive power.

### DETAILED DESCRIPTION OF THE PREFERRED EMBODIMENTS

Preferred embodiments of a method for processing a substrate and a method for manufacturing a semiconductor device, according to the present invention will specifically be described. Although the specific materials, conditions and numeral conditions or the like might be used in the following description, these are no more than one of preferred examples. Therefore, the present invention is by no means limited by or to these.

### First Preferred Embodiment

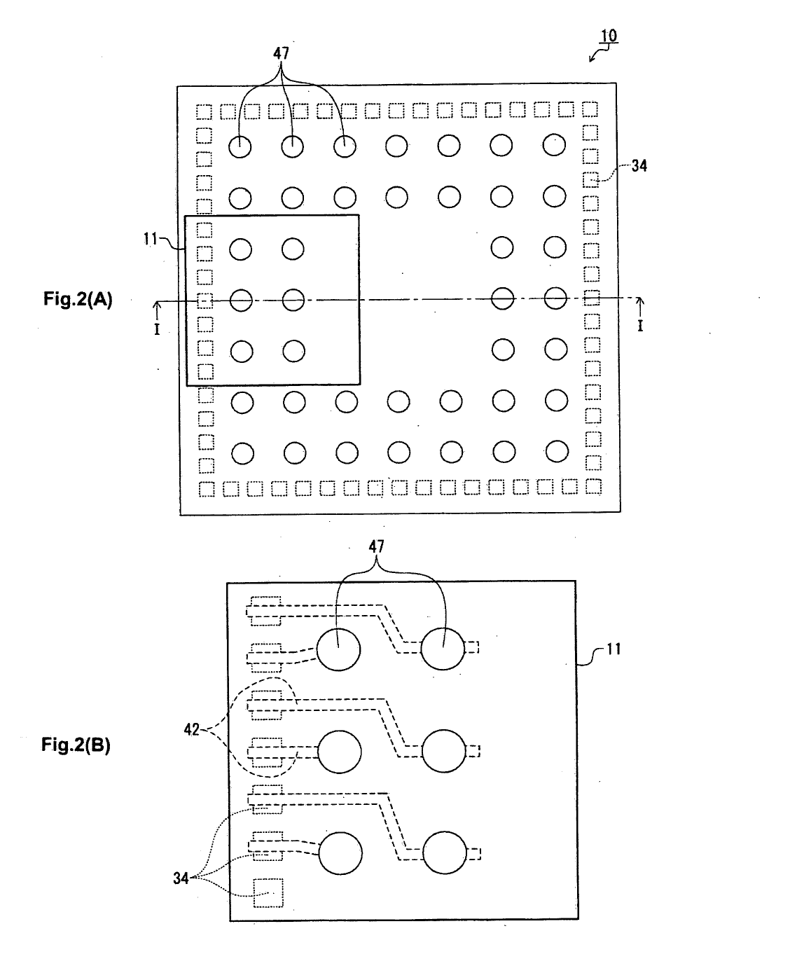

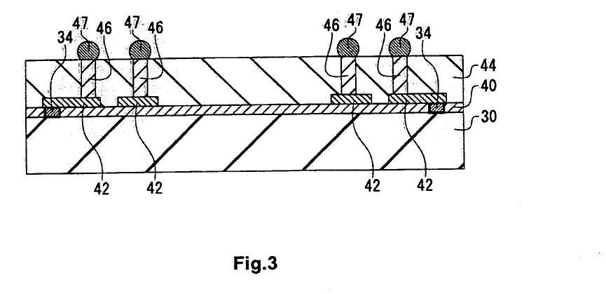

A sample is first prepared. The present sample has a form similar to the W-CSP already described with reference to FIGS. 2 and 3 except that no encapsulating resin is provided.

Described specifically, the sample has a semiconductor chip in which a plurality of electrode pads are disposed along its peripheral edge.

Also the sample has an insulating film which exposes the electrode pads, on the semiconductor chip. As materials for the insulating film, which are applicable to a plasma processing process or step of the present invention, may be mentioned, resins such as a polyimide resin, an epoxy resin, a silicone resin, a phenolic resin, a polyester resin, an acrylic resin, polybenzooxazol (PBO) and benzo-cyclo-butene (BCB), etc. Particularly preferred may be the polyimide resin or epoxy resin. In the present sample, the polyimide resin was used as the insulating film.

Further, the sample has copper wirings. Each of the copper wirings extends over the insulating film and has one end connected to its corresponding electrode pad and the other end connected to its corresponding copper post.

Although the sample is not provided with the encapsulating resin, the encapsulating resin for sealing the insulating film, copper wirings and copper posts is provided where the already-described W-CSP is adopted as an actual semiconductor device.

As the encapsulating resin suitable if applied to the plasma processing process of the present invention, an arbitrary and suitable one can be selected from a thermosetting resin, a thermoplastic resin, etc. known to date per se in the art. Particularly preferred may be the epoxy resin and the polyimide resin. In the present sample, the thermosetting epoxy resin was used as the encapsulating resin.

Plasma processing was effected on the sample. This plasma processing was executed by ionizing and radicalizing a reactive gas by an inductively coupled discharge system using an apparatus known to date.

Upon the plasma processing of the present invention, activated species that exist within a chamber include electrons, ions and radicals. While these electrons, ions and radicals can coexist within the chamber simultaneously, abundance ratios of these in the chamber can suitably be determined as such a condition that the ions are used as the activated species or such a condition that the radicals are used as the activated species, by setting power to be applied, a gas flow rate, pressure and the type of gas to arbitrary and suitable conditions.

If, for example, the ions are used as the main activated species in plasma processing using the oxygen gas commonly used in the art, then satisfactory moisture-resistance reliability can be ensured. If, however, the radicals are used as the main activated species, then the moisture-resistance reliability is deteriorated.

Even under any condition like such a condition that the ions are used as the main activated species or such a condition that the radicals are used as the main activated species, in the case of the plasma processing using nitrogen-type gas, according to the invention of the present application, adhesive power between the encapsulating portion and each of the copper wirings and copper posts corresponding to constituent elements with copper as a material is also remarkably enhanced as well as the adhesion between the encapsulating portion (encapsulating resin) and the insulating film. It is thus possible to ensure even moisture-resistance reliability.

The term “such a condition that the ions are defined as the main activated species” mentioned here means a condition that processing pressure is low, i.e., a condition that the pressure is set to, for example, 40 Pa (300 mTorr) or so even at the maximum. Generally, the higher the degree of vacuum, the longer the mean free path of ions. Thus, the amount of ions supplied to the surface of the sample is brought to a state of becoming larger than the amount of radicals.

The term “such a condition that the radicals are defined as the main activated species” mentioned here means the condition that the pressure is made high as compared with the already-described term “such a condition that the ions are defined as the main activated species”.

As the condition that the radicals are defined as the main activated species, may preferably be mentioned, for example, a condition that the applied power is set as 200 W or higher and the pressure is set to 66.5 Pa (500 mTorr) or less.

That is, since the degree of vacuum is set lower, the mean free path of ions is small and the ions are deactivated soon. Therefore, when the pressure is high, the amount of radicals is brought to a state of becoming larger than the amount of ions.

The plasma processing may preferably be set as such a process that, for example, the applied power is set to 1000 W (watts) even at the maximum, the flow rate of the nitrogen-type gas is set to 500 sccm even at the maximum and a stage temperature is set to 100° C. even at the maximum, and in this condition, the plasma processing is done for 20 seconds even in the shortest time.

In the present example, the plasma processing was done for 20 seconds assuming that the applied power is set to 500 W, the flow rate of the nitrogen-type gas is set to 200 sccm and the pressure is set to 200 mTorr, i.e., 26.7 Pa, that is, “the condition that the ions are defined as the main activated species” is met, and the stage temperature is set to 80° C.

As the nitrogen-type gas, any gas can be used if gases such as nitrogen gas, ammonia gas and hydrazine gas are adopted singly or gases containing nitrogen such as a mixed gas of these, etc. are adopted.

The sample processed by the plasma processing of the present invention has nitrogen-type groups bound to the surfaces (exposed surfaces) of the insulating film and the copper wirings. The term “nitrogen group” mentioned here means a group containing nitrogen, such as an amino group, an amide group or the like.

Bonding formed by the nitrogen-type groups and functional groups of the encapsulating resin, which are bound to the surfaces of the insulating film and each constituent element with copper as the material, is strong. At the mention of the adhesion between the insulating film and the encapsulating resin in particular in addition to the above, the degree of depressions and projections or irregularity developed in the insulating film by the plasma processing using the nitrogen gas is larger than the degree of irregularity produced by the plasma processing using the oxygen gas.

Thus, according to the plasma processing process of the invention of the present application, an exposed surface which exhibits a larger (chemical) bonding can be formed without surface-roughening an exposed surface that impairs electrical characteristics.

According to the plasma processing using the nitrogen gas, of the present invention, the surfaces of the wirings and copper posts using copper as the material are nitrided so that the adhesion to the encapsulating film is more enhanced. Thus, even though they are placed under, for example, high-temperature and high-humidity stress, a reduction in the power of adhesion to the encapsulating resin with time can remarkably be suppressed by virtue of such surface nitriding.

According to the first embodiment, the following advantageous effects are obtained.

(1) The adhesion of the encapsulating resin to the respective surfaces of the insulating film and constituent elements with copper as the material is improved. Therefore, the adhesion among the insulating film, the constituent elements with copper as the material, and the encapsulating resin is strengthened. As a result, moisture-resistance reliability is enhanced.

(2) Similar advantageous effects are obtained with respect to various insulating films. Since a margin for a processing condition is wide, a burden on a condition statement is reduced.

(3) Impact given to the environment is small because of dry processing.

(4) Although a resin encapsulating step cannot be performed immediately after the execution of the conventional oxygen plasma processing, the resin encapsulating step can be carried out at once if the plasma processing of the present invention using the nitrogen gas is performed. Thus, TAT can be more shortened.

### Second Preferred Embodiment

In the second embodiment, plasma processing was executed on condition that copper wirings and copper posts are discolored brown, using a sample having the same form as that employed in the already-described first embodiment and using nitrogen gas.

The term “discolored brown” mentioned here means a state in which the constituent elements using copper as the material, i.e., the copper wirings and copper posts show or turn brown as if their surfaces were oxidized although not oxidized, by subjecting them to the plasma processing process or step of the present invention. This is considered to occur because the degree of nitriding of copper is high.

The plasma processing process may preferably be set as such a process that, for example, power to be applied is set to 1000 W even at the maximum, the flow rate of nitrogen-type gas is set to 500 sccm even at the maximum and a stage temperature is set to 100° C. even at the maximum, and plasma processing is executed for 45 seconds even in the shortest time to thereby bring exposed surfaces of the constituent elements using the above copper as the material to brown.

In the present example, the plasma processing is performed as a process in which it is done for 60 seconds assuming that the applied power is 500 W, the flow rate of nitrogen gas is 200 sccm and the pressure is 26.7 Pa (200 mTorr), that is, “the condition that ions are defined as main activated species” is met, and the stage temperature is 80° C.

According to the plasma processing of the present embodiment, adhesive power similar to that obtained in the first embodiment can be obtained. Further, according to the plasma processing, the immobilization of copper can be promoted because the plasma processing is done to such a degree that the surface (exposed surface) of copper used as the material turns brown. As a result, age-based deterioration of adhesive power to an encapsulating resin can be suppressed more effectively.

As the scale-down of wirings per se and wiring intervals goes further forward with finer process rules, it is becoming increasingly difficult to ensure moisture-resistance reliability in particular.

According to the plasma processing process of the second embodiment, that is, if the plasma processing is performed on the condition that the ions are defined as the main activated species, up to such an extent that the exposed surface of each constituent element with copper as the material is discolored brown, then more satisfactory moisture-resistance reliability can be ensured.

Incidentally, although the above embodiment has performed the plasma processing using the nitrogen gas on the condition that the ions are defined as the main activated species, the plasma processing may be performed by mixing nitrogen gas with trace amounts of additive gases, e.g., He, H₂, H₂O and the like for the purpose of adjusting a plasma state, the type of activated species or the amount of production. Further, the plasma processing may be carried out using as nitrogen-type gas, a sort of gas selected from a group containing nitrogen gas, ammonia gas and hydrazine gas or mixed gas obtained by arbitrarily combining two or more sorts of gases selected therefrom.

The W-CSP in which the insulating film, redistribution wiring layer (copper wirings) and electrode posts (copper posts) are provided on the semiconductor chip, has been illustrated and explained as the sample. That is, although the plasma processing process using the nitrogen-type gas according to the present invention has been explained as being so suitable if applied to the manufacturing process of the semiconductor device, the plasma processing process using the nitrogen-type gas can be applied to a surface modification process for a substrate corresponding to, e.g., a BT resin substrate or an epoxy resin substrate, wherein constituent elements with copper as a material are exposed from its surface.

Further, although the above embodiment makes use of each fractionized semiconductor chip, the plasma processing process using the nitrogen-type gas is effected on a semiconductor wafer (silicon wafer) in process of manufacture at a wafer level, and thereafter a fractionizing process or step may of course be performed after the completion of the manufacturing process of the semiconductor device at the wafer level.

### Third Preferred Embodiment

A third embodiment is characterized in that a heat treatment step is further executed after a plasma processing step using nitrogen-type gas.

The heat treatment step may be effected on objects (fractionalized chips and semiconductor wafer) to be processed subsequent to the execution of the plasma processing step of the first or second embodiment already described above, preferably for 30 seconds or so as a temperature range of 170° C. to 180° C., for example.

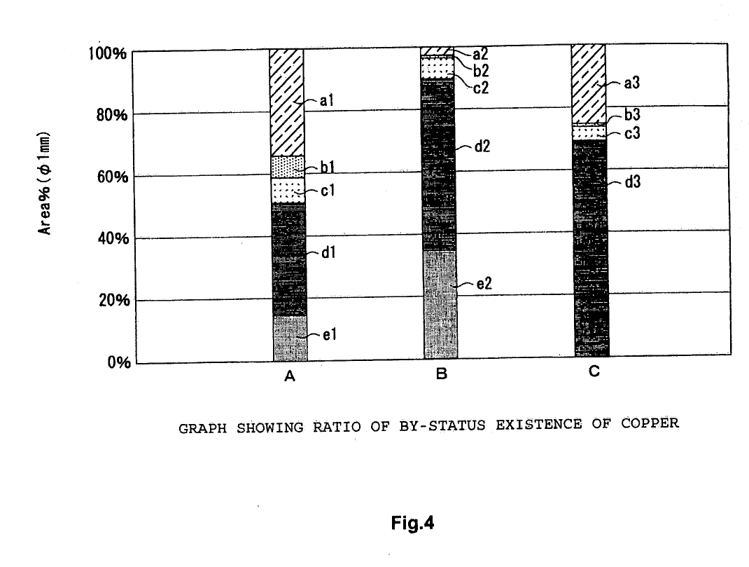

Incidentally, the heat treatment step can be shared by a step with heat treatment like a resin encapsulating step, e.g., die's preheating or the like in the resin encapsulating step. A description will be made of variations in the ratio of existence-by status of copper by the heat treatment step referring to FIG. 4.

FIG. 4 is a graph showing the ratio of by-status existence of copper per unit area (area of a circle having a diameter φ of 1 mm in the present example). A graph A indicates an example in which a plasma processing step using nitrogen-type gas is not executed. A graph B indicates an example in which only the plasma processing step using the nitrogen-type gas is executed and no heat treatment is done. A graph C indicates an example in which the plasma processing step using the nitrogen-type gas and the heat treatment step are performed.

Incidentally, nitrogen derived from the plasma processing is desorbed from an exposed surface (surface) of each of structures such as wirings and electrode posts with copper as the material by the heat treatment step. At this time, a small quantity of nitrogen remains inside the structure with copper as the material.

Variations in the ratio of by-status existence of copper were detected and analyzed by an X-ray photoelectron spectroscopy (XPS) method.

An area ax (symbol x indicates 1, 2 or 3, x=1 corresponds to the graph A, x=2 corresponds to the graph B, and x=3 corresponds to the graph C, and other areas are hereinafter the same as this) indicates the ratio of existence of Cu(OH)₂. An area bx indicates the ratio of existence of CuCO₃, an area cx indicates the ratio of existence of CuO, an area dx indicates the ratio of existence of Cu₂O, and an area ex indicates the ratio of existence of metal Cu.

It is understood that as indicated by the graph A, the ratio of Cu(OH)₂ equivalent to the area al is relatively high like 30% or more when the plasma processing step using the nitrogen-type gas is not executed. It is also understood that the ratio of Cu₂O equivalent to the area d1 is 40% or so. It is further understood that the ratio of metal Cu equivalent to the area e1 is 10% or more.

It is understood that as indicated by the graph B, the ratio of Cu(OH)₂ equivalent to the area a2 noticeably decreases as compared with the area a1 of the graph A where the plasma processing using the nitrogen-type gas is executed. It is also understood that the ratio of Cu₂O indicated by the area d2 and the ratio of metal Cu indicated by the area e2 increase.

When the plasma processing step and the heat treatment are performed, Cu₂O indicated by the area d3 takes up 60% or more and result in a dominant constituent element as indicated by the graph C. It is found at this time that Cu(OH)₂ indicated by the area a3 increases up to 20% or more in proportion by execution of the heat treatment.

With the execution of the plasma processing, or the plasma processing and the heat treatment in this way, Cu₂O becomes dominant, i.e., it indicates the ratio of existence of 50% even at a minimum with respect to the ratio of existence of copper.

Thus, when Cu₂O becomes dominant over the surface of the structure with copper as the constituent element, e.g., when an encapsulating portion formed by an encapsulating resin coated in contact with the structure exists, the power of adhesion between the structure and the encapsulating portion can noticeably be increased.

Although the strength of a bonded part formed at this time is described in detail later, the adhesive power is hard to drop because it is hard to erode owing to the plasma processing and the heat treatment even though it is placed under high-temperature and high-humidity environments, for example.

### COMPARATIVE EXAMPLE 1

A sample identical in construction to that employed in the first embodiment already described above was prepared as the comparative example 1. Incidentally, no plasma processing and heat treatment are effected on the sample (untreated).

### COMPARATIVE EXAMPLE 2

As the comparative example 2, plasma processing was executed using a sample having the same configuration as that employed in the first embodiment. In the present example, a plasma processing condition is set assuming that power to be applied is 500 W (watts), the flow rate of oxygen gas is 200 sccm, and the pressure is 26.7 Pa (200 mTorr), that is, the “condition that ions are defined as main activated species” is met, and a stage temperature is 80° C. and a processing time interval is 15 seconds. Thus, the present example shows an example in which a conventional plasma processing process is performed.

### COMPARATIVE EXAMPLE 3

As the comparative example 3, plasma processing was carried out using a sample having the same configuration as that employed in the first embodiment. In the present example, a plasma processing condition is set assuming that power to be applied is 500 W (watts), the flow rate of nitrogen-type gas is 200 sccm, and the pressure is 26.7 Pa (200 mTorr), that is, the “condition that radicals are defined as main activated species” is met, and a stage temperature is 80° C. and a processing time interval is 60 seconds.

(Shear Strength Test)

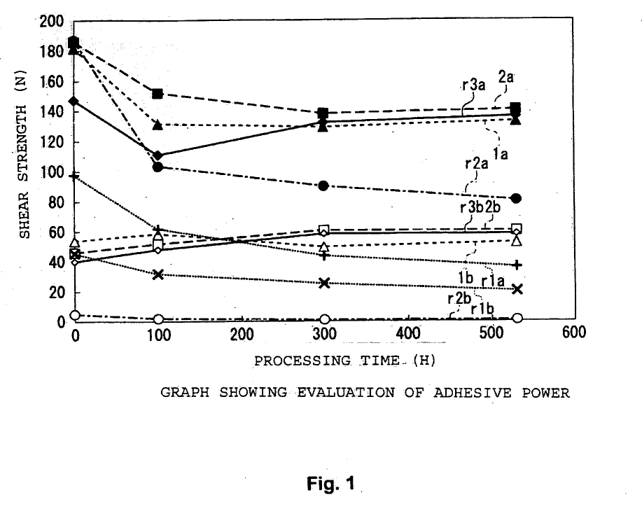

A so-called shear strength test made to evaluate adhesive power among an encapsulating resin, an insulating film (polyimide resin) and copper, and the result thereof will now be explained with reference to FIG. 1.

FIG. 1 is a graph showing the results of shear strength tests on the samples in which the plasma processing processes of the above first and second embodiments and comparative examples 1 (non-treated), 2 and 3 are carried out.

The shear strength test was done by subjecting each sample to a so-called high-temperature and high-humidity stress processing condition for a predetermined time interval. The high-temperature and high-humidity stress processing condition mentioned here means the condition that the temperature is assumed to be 12°1 C. and relative humidity is assumed to be 100% (RH).

In FIG. 1, the horizontal axis indicates a processing time (H), and the vertical axis indicates a shear strength (N: Newton).

Incidentally, a method for testing the shear strength was executed in accordance with the following method.

Samples each having a size of 8 mm×8 mm, which have been subjected to the plasma processing processes of the first and second embodiments and the plasma processing processes of the comparative examples 1 (untreated), 2 and 3, are respectively fixed onto a support body. Then,.columnar encapsulating resin blocks each having a 2 mm×2 mm square are formed in their corresponding central upper surfaces of the samples. Thereafter, loads are imposed thereon from the transverse direction and strengths (N) at the time that the columnar encapsulating resin blocks were peeled from the surface of a semiconductor chip, were measured.

A pass/fail criterion at the shear strength test is 120N or more both before high-temperature and high-humidity stress processing and after the high-temperature and high-humidity stress processing as to the strengths of an encapsulating resin and an insulating film. As to the strengths of the encapsulating resin and copper (constituent elements like wirings or copper posts), the pass/fail criterion thereat is 40N or more both before high-temperature and high-humidity stress processing and after the high-temperature and high-humidity stress processing.

In FIG. 1, a chain line r1a indicated by a plot of signs “+” indicates an adhesive strength of the insulating film relative to the encapsulating resin of the comparative example 1, i.e., the non-treated sample. A chain line r1b indicated by a plot of signs “x” indicates an adhesive strength of copper (constituent element with copper as the material) relative to the encapsulating resin of the comparative example 1, i.e., the untreated sample.

A chain line 1a indicated by a plot of signs “▴” indicates an adhesive strength of the insulating film relative to the encapsulating resin of the sample subjected to the plasma processing of the first embodiment. A chain line 1b indicated by a plot of signs “□” indicates an adhesive strength of copper (constituent element with copper as the material) relative to the encapsulating resin of the sample of the first embodiment.

A chain line 2a indicated by a plot of signs “▪” indicates an adhesive strength of the insulating film relative to the encapsulating resin of the sample of the second embodiment. A chain line 2b indicated by a plot of signs “□” indicates an adhesive strength of copper (constituent element with copper as the material) relative to the encapsulating resin of the sample of the second embodiment.

A chain line r2a indicated by a plot of signs “●” indicates an adhesive strength of the insulating film relative to the encapsulating resin of the sample of the comparative example 2. A chain line r2b indicated by a plot of signs “◯” indicates an adhesive strength of copper (constituent element with copper as the material) relative to the encapsulating resin of the sample of the comparative example 2.

A solid line r3a indicated by a plot of signs “□” indicates an adhesive strength of the insulating film relative to the encapsulating resin of the sample of the comparative example 3. A solid line r3b indicated by a plot of signs “□” indicates an adhesive strength of copper (constituent element with copper as the material) relative to the encapsulating resin of the sample of the comparative example 3.

The evaluation of adhesive power in the plasma processing process of the first embodiment will be explained with reference to FIG. 1.

At the mention of adhesive power between the encapsulating resin and the insulating film, the adhesive strength prior to the high-temperature and high-humidity stress processing, i.e., in an initial state is enhanced, and aged degradation of the adhesive power is suppressed even under the high-temperature and high-humidity stress.

On the other hand, it is estimated that in the sample (comparative example 2: refer to the graphs r2a and r2b) subjected to the conventional oxygen plasma processing, strong bonding other than hydrogen bonding has been developed in the bonded surface between the encapsulating resin and the insulating film where the occurrence of the aged degradation of the adhesive power is taken into consideration. It is understood from the relationship between the encapsulating resin and copper that the adhesive power is hardly developed in the conventional oxygen plasma processing.

That is, although the aged degradation of the adhesive power is less reduced in the sample subjected to the plasma processing of the first embodiment, this is considered to result from the fact that physical adhesive power relative to the surface-roughened surface, i.e., chemical adhesive power other than adhesive power based on a so-called anchor effect has been manifested.

The evaluation of adhesive power in the plasma processing process of the second embodiment will be explained with reference to FIG. 1.

The adhesive power between the encapsulating resin and the insulating film and the adhesive power between the encapsulating resin and copper are both approximately equivalent to the first embodiment.

It is however understood that in the sample subjected to the plasma processing of the second embodiment, the degree of aged degradation of the adhesive power is low as compared with the sample of the first embodiment.

It is also understood that although not explained in detail, the elution (corrosion) of copper wirings is remarkably suppressed as a result of an analysis (evaluation of moisture-resistance reliability) of a semiconductor product subsequent to the completion of the high-temperature and high-humidity stress processing. That is, it is understood that the immobilization of copper is promoted by performing plasma processing to the extent that copper is discolored brown.

The adhesive power of the sample according to the comparative example 1 will be explained with reference to FIG. 1. It is understood that the adhesive power (refer to the graph r1a) between the encapsulating resin and the insulating film is weak even as compared with any of the embodiments and comparative examples. Since the irregularity of the surface does not occur and a hydrophilic group that creates hydrogen bonding is also reduced where no plasma processing is done, the adhesive power is considered to be low.

It is understood that the adhesive power (graph 1rb) between the encapsulating resin and copper becomes larger than that in the sample (comparative example 2: refer to the graph r2b) subjected to the conventional oxygen plasma processing. This is considered to result from the fact that the state of an exposed surface is deteriorated due to the oxygen plasma processing.

The adhesive power of the sample of the comparative example 2 will be explained with reference to FIG. 1.

It is understood that while the adhesive power (refer to the graph r2a) between the encapsulating resin and the insulating film is large to a certain degree upon an exposure initial stage, the degree of aged degradation is large. This is considered to result from the fact that the development of adhesive power depends only on hydrogen bonding.

It is understood that the adhesive power (refer to the graph r2b) between the encapsulating resin and copper is hardly developed. This is considered to result from the fact that the quality of an oxide film formed in an exposed surface by the oxygen plasma processing is poor.

The adhesive power of the sample according to the comparative example 3 will be explained with reference to FIG. 1.

The adhesive power between the encapsulating resin and the insulating film and the adhesive power between the encapsulating resin and copper are both approximately equivalent to the first embodiment.

Incidentally, a result equivalent to that of the first embodiment is obtained even from the viewpoint of moisture-resistance reliability in the case of the comparative example 3. Since, however, modification efficiency is low in the case of the “condition that the radicals are defined as the main activated species” in the plasma processing as compared with the “condition that the ions are defined as the main activated species”, a long processing time is taken.

It can thus be said that the plasma processing executed on the “condition that the ions are defined as the main activated species” is excellent in terms of the viewpoint of throughput.

(Share Strength Test 2)

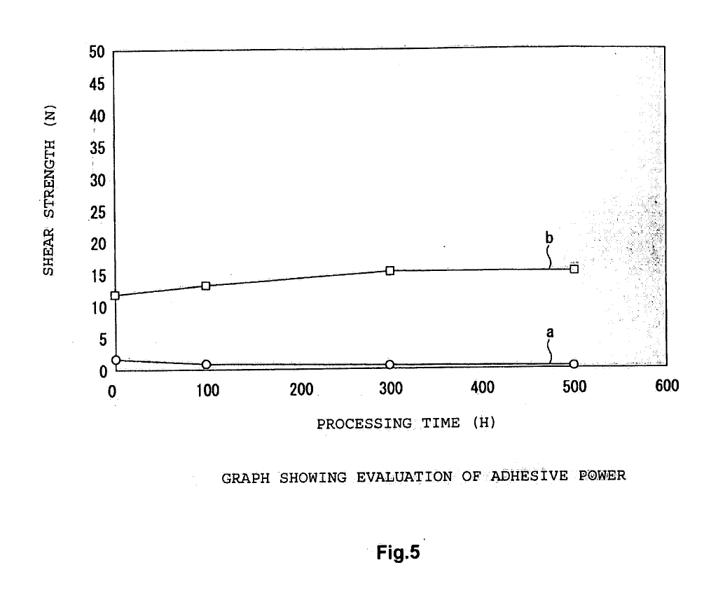

Referring to FIG. 5, a description will be made of a so-called share strength test for evaluating the power of adhesion between an encapsulating resin and a non-treated copper structure or between the encapsulating resin and a copper structure subjected to the plasma processing and heat treatment, and the result of its evaluation.

FIG. 5 is a graph showing the result of a share strength test on each of the samples of the third embodiment and the comparative example 1 (untreated).

The share strength test was carried out by exposing the sample to a so-called high-temperature and high-humidity stress processing condition for a predetermined period of time. The high-temperature and high-humidity stress processing condition mentioned here refers to, specifically, a condition under which the temperature is 12120 C. and the relative humidity is 100% (RH).

In FIG. 5, the horizontal axis indicates a processing time (H), and the vertical axis indicates a share strength (N: Newton), respectively.

Incidentally, since the test method is similar to the already-described share strength test 1, its detailed description is omitted.

In FIG. 5, a solid line a indicated by a plot of signs “◯” indicates the power of adhesion of copper (constituent element with copper as a material) to the encapsulating resin of the untreated sample.

A solid line b indicated by a plot of signs “□” indicates the power of adhesion of copper (constituent element with copper as the material) to the encapsulating resin of the sample subjected to the plasma processing and heat treatment of the third embodiment.

It is understood that as is apparent from the graph indicated by the solid line b, the sample subjected to the plasma processing and heat treatment is increased five times in adhesive power (share strength) as compared with the untreated sample. It is also understood that the sample subjected to the plasma processing and heat treatment does not cause aged degradation in adhesive power even when the processing time (high-temperature and high-humidity stress exposure time) has reached 500 hours.

It has been found from the above that if the plasma processing using the nitrogen-type gas according to the invention of the present application is performed as the “condition that the ions are defined as the main activated species”, then the adhesive strength is remarkably enhanced even in both of the relations between the encapsulating resin and the insulating film and between the encapsulating resin and copper (wirings and posts). It is also understood that aged degradation of the adhesive power is effectively suppressed even under, for example, hostile use conditions like the high-temperature and high-humidity stress condition and the like, aside from the adhesive strength.

Further, it has been found that if the plasma processing and heat treatment are carried out and the ratio of existence of Cu₂O is made dominant, i.e., it is set to 50% or so even at a minimum with respect to the ratio of existence of the surface of the structure with copper as the material, then the adhesive strength can be greatly increased. Furthermore, it has been found that if the plasma processing and the heat treatment are performed, then aged degradation in adhesive power can effectively be prevented by effectively preventing erosion.

In the above description, the wirings and posts have been illustrated as the example illustrative of the constituent elements with copper as the material. However, the present invention is not limited to them. If only other structure with copper as the material is exposed on a substrate and exists therein, for example, then an advantageous effect similar to the above can be obtained even in the relationship between such a structure and the encapsulating resin.

While the preferred forms of the present invention have been described, it is to be understood that modifications will be apparent to those skilled in the art without departing from the spirit of the invention. The scope of the invention is to be determined solely by the following claims.

What is claimed is:

1. A method for modifying a surface of a substrate having an insulating film and constituent elements with copper as a material, including wirings provided over the insulating film, said method comprising the steps of:
preparing the substrate selected from a group containing a BT resin substrate and an epoxy resin substrate; and
effecting plasma processing on the substrate using nitrogen-type gas.

2. The method according to claim 1, wherein said plasma processing step is a step for setting pressure to 40 Pa even at a maximum to thereby perform the plasma processing with ions as main activated species.

3. The method according to claim 2, wherein said plasma processing step is a step for setting pressure to 26.7 Pa to thereby perform the plasma processing with ions as main activated species.

4. The method according to claim 2, wherein said plasma processing step is a step for performing the plasma processing for 20 seconds even in a shortest time assuming that power to be applied is 1000 W even at a maximum, the flow rate of nitrogen-type gas is 500 sccm even at a maximum, and a stage temperature is 100° C. even at a highest temperature.

5. The method according to claim 4, wherein said plasma processing step is a step for performing the plasma processing for 20 seconds assuming that power to be applied is 500 W, the flow rate of nitrogen-type gas is 200 sccm and a stage temperature is 80° C.

6. The method according to claim 2, wherein said plasma processing step is a step for performing the plasma processing for 45 seconds even in a shortest time assuming that power to be applied is 1000 W even at a maximum, the flow rate of nitrogen-type gas is 500 sccm even at a maximum and a stage temperature is 100° C. even at a highest temperature, thereby to turn brown an exposed surface of each of the constituent elements with said copper as the material.

7. The method according to claim 6, wherein said plasma processing step is a step for performing the plasma processing for 60 seconds assuming that power to be applied is 500 W, the flow rate of nitrogen gas is 200 sccm, and a stage temperature is 80° C., thereby to turn brown an exposed surface of each of the constituent elements with said copper as the material.

8. The method according to claim 1, wherein said plasma processing step is a step for effecting the plasma processing on the substrate in which the insulating film is formed of a material selected from a resin group containing a polyimide resin, an epoxy resin, a silicone resin, a phenolic resin, a polyester resin, an acrylic resin, polybenzooxazol and benzo-cyclo-butene.

9. The method according to claim 1, wherein said plasma processing step is a step for performing the plasma processing using, as the nitrogen-type gas, a sort of gas selected from a group containing nitrogen gas, ammonia gas and hydrazine gas or mixed gas obtained by arbitrarily combining two or more sorts of gases selected therefrom.

10. The method according to claim 1, wherein after said plasma processing step, heat treatment for increasing the ratio of existence of Cu₂O with respect to the ratio of existence of copper on the surface of each of the constituent elements with copper as the material is further performed.

11. The method according to claim 10, wherein said heat treatment step is a heat treatment step for setting the ratio of existence of Cu₂O per unit area of the surface of each of the constituent elements with copper as the material to 50% even at a minimum.

12. The method according to claim 10, wherein said heat treatment step is a heat treatment step executed for 30 seconds in a temperature range of 170° C. to 180° C.

13. A method for manufacturing a semiconductor device, comprising the steps of:
forming an insulating film over a substrate;
forming constituent elements with copper as a material, including wirings over the insulating film;
effecting plasma processing on exposed surfaces of the insulating film and the constituent elements provided over the substrate, using nitrogen-type gas; and
forming an encapsulating portion which seals the exposed surfaces of the insulating film and the constituent elements so as to cover the exposed surfaces thereof.

14. The method according to claim 13, herein said plasma processing step is a step for setting pressure to 40 Pa even at a maximum to thereby perform the plasma processing with ions as main activated species.

15. The method according to claim 14, wherein said plasma processing step is a step for setting pressure to 26.7 Pa to thereby perform the plasma processing with ions as main activated species.

16. The method according to claim 14, wherein said plasma processing step is a step for performing the plasma processing for 20 seconds even in a shortest time assuming that power to be applied is 1000 W even at a maximum, the flow rate of nitrogen-type gas is 500 sccm even at a maximum, and a stage temperature is 100° C. even at a highest temperature.

17. The method according to claim 16, wherein said plasma processing step is a step for performing the plasma processing for 20 seconds assuming that power to be applied is 500 W, the flow rate of nitrogen-type gas is 200 sccm and a stage temperature is 80° C.

18. The method according to claim 14, wherein said plasma processing step is a step for performing the plasma processing for 45 seconds even in a shortest time assuming that power to be applied is 1000 W even at a maximum, the flow rate of nitrogen-type gas is 500 sccm even at a maximum and a stage temperature is 100° C. even at a highest temperature, thereby to turn brown an exposed surface of each of the constituent elements with said copper as the material.

19. The method according to claim 18, wherein said plasma processing step is a step for performing the plasma processing for 60 seconds assuming that power to be applied is 500 W, the flow rate of nitrogen gas is 200 sccm, and a stage temperature is 80° C., thereby to turn brown an exposed surface of each of the constituent elements with said copper as the material.

20. The method according to claim 13, wherein said insulating film forming step is a step for forming the insulating film by a material selected from a resin group containing a polyimide resin, an epoxy resin, a silicone resin, a phenolic resin, a polyester resin, an acrylic resin, polybenzooxazol and benzo-cyclo-butene, and
wherein said encapsulating portion forming step is a step for forming the encapsulating portion by a material selected from a group containing an epoxy resin and a polyimide resin.

21. The method according to claim 13, wherein said plasma processing step is a step for performing the plasma processing using, as the nitrogen-type gas, a sort of gas selected from a group containing nitrogen gas, ammonia gas and hydrazine gas or mixed gas obtained by arbitrarily combining two or more sorts of gases selected therefrom.

22. The method according to claim 13, wherein said plasma processing step is a step for effecting the plasma processing on the substrate prior to a fractionizing step and further includes a fractionizing step after the said plasma processing step.

23. The method according to claims 13, wherein after said plasma processing step heat treatment for increasing the ratio of existence of Cu₂O with respect to the ratio of existence of copper on the surface of each of the constituent elements with copper as the material is further performed.

24. The method according to claim 23, wherein said heat treatment step is a heat treatment step for setting the ratio of existence of Cu₂O per unit area of the surface of each of the constituent elements with copper as the material to 50% even at a minimum.

25. The method according to claim 23, wherein said heat treatment step is a heat treatment step executed for 30 seconds in a temperature range of 170° C. to 180° C.

26. The method according to claim 23, wherein said plasma processing step is a step performed on the substrate prior to the fractionizing step, and the heat treatment step is executed after said plasma processing step and the fractionizing step is further executed after the heat treatment step.

27. A semiconductor device wherein the ratio of existence of Cu₂O per unit area of a surface of each of constituent elements with copper formed on a semiconductor substrate as a material is set as 50% even at a minimum.
